(19) United States
(12) Patent Application Publication
(10) Pub. No.: US 2024/0243179 A1
(43) Pub. Date: Jul. 18, 2024

(54) SEMICONDUCTOR DEVICE AND MANUFACTURING METHOD THEREOF

(71) Applicant: Huawei Digital Power Technologies Co., Ltd., Shenzhen (CN)

(72) Inventors: Hui Sun, Shenzhen (CN); Biao Gao, Dongguan (CN); Zhibin Chen, Dongguan (CN); Yong Hou, Dongguan (CN)

(73) Assignee: Huawei Digital Power Technologies Co., Ltd., Shenzhen (CN)

(21) Appl. No.: 18/622,845

(22) Filed: Mar. 29, 2024

Related U.S. Application Data
(63) Continuation of application No. PCT/CN2022/099667, filed on Jun. 20, 2022.

(30) Foreign Application Priority Data
Sep. 30, 2021 (CN) 202111163668.4

(51) Int. Cl. H01L 29/423; H01L 21/285; H01L 21/3213; H01L 29/20; H01L 29/40; H01L 29/66; H01L 29/778

(52) U.S. Cl. CPC H01L 29/42316; H01L 21/28581; H01L 21/32134; H01L 21/32139; H01L 29/2003; H01L 29/401; H01L 29/66462; H01L 29/7786

(57) ABSTRACT

A semiconductor device includes a channel layer and a barrier layer that are sequentially stacked, a doped layer, and a gate structure. The channel layer and the barrier layer each are made of a group III nitride material. The barrier layer includes a gate region. The doped layer is located on a side of the barrier layer that is away from the channel layer. The doped layer is located in the gate region. A material of the doped layer is a group III-V compound including a receptor-type doped element.

### CROSS-REFERENCE TO RELATED APPLICATIONS

This application is a continuation of International Application No. PCT/CN2022/099667, filed on Jun. 20, 2022, which claims priority to Chinese Patent Application No. 202111163668.4, filed on Sep. 30, 2021. The disclosures of the aforementioned applications are hereby incorporated by reference in their entireties.

### TECHNICAL FIELD

This application relates to the field of semiconductor manufacturing technologies, and in particular, to a semiconductor device and a manufacturing method thereof.

### BACKGROUND

Wide-bandgap semiconductor gallium nitride (GaN) has a high breakdown electric field, high electron mobility, and a high saturated electron drift velocity, and has a wide application prospect in the field of power electronics and radio frequency microwave.

Currently, a gallium nitride device mainly includes a device based on an aluminum gallium nitride (AlGaN)/GaN heterostructure, for example, a high electron mobility transistor (HEMT) manufactured by using an AlGaN/GaN heterostructure as a core. The HEMT has excellent performance, is very suitable for manufacturing a power semiconductor device, and is currently widely concerned in the industry. Piezoelectric polarization and spontaneous polarization that are generated by the AlGaN/GaN cause a high concentration of two-dimensional electron gas (2-DEG) to be formed at an interface of the heterostructure, and mobility and a saturation velocity of the 2-DEG are far higher than those of silicon.

In the gallium nitride device, a doped layer may be formed on the surface of the AlGaN/GaN heterostructure of a gate region, a gate structure is formed on the doped layer, and stacked doped layer and gate structure are formed. The doped layer may be a p-type GaN (p-GaN) layer or a p-type AlGaN (p-AlGaN) layer. When the gallium nitride device of such a structure works, a side wall of the gate structure and a side wall of the doped layer form a leakage channel, and consequently an electrical parameter such as gate leakage (Igleak) is affected.

### SUMMARY

In view of this, embodiments of this application provide a semiconductor device and a manufacturing method thereof, so as to improve device performance.

According to a first aspect of embodiments of this application, a semiconductor device and a manufacturing method thereof are provided. The semiconductor device may include a channel layer and a barrier layer that are sequentially stacked, a doped layer, and a gate structure. The channel layer and the barrier layer each are made of a group III nitride material. The barrier layer has a gate region. The doped layer is located on a side that is of the barrier layer and that is away from the channel layer. The doped layer is located in the gate region. A material of the doped layer is a group III-V compound including a receptor-type doped element. The gate structure is located on a side that is of the doped layer and that is away from the channel layer. A side wall that is of the gate structure and that is close to the doped layer is retracted relative to a side wall of the doped layer, and the side wall that is of the gate structure and that is close to the doped layer is retracted relative to a side wall that is of the gate structure and that is away from the doped layer, so that the side wall of the gate structure and the side wall of the doped layer are not in a same plane. A retraction structure of the side wall that is of the gate structure and that is close to the doped layer blocks contact between the side wall that is of the gate structure and that is away from the doped layer and the side wall of the doped layer, which is equivalent to blocking a leakage channel between the gate structure and the doped layer, thereby reducing a leakage current of the device and improving device performance.

In an implementation, a material of the channel layer is gallium nitride, a material of the barrier layer is aluminum gallium nitride, and a material of the doped layer is gallium nitride or aluminum gallium nitride that includes the receptor-type doped element.

In this embodiment of this application, the material of the channel layer may be gallium nitride, the material of the barrier layer is aluminum gallium nitride, and two-dimensional electron gas may be formed at an interface between the channel layer and the barrier layer. The material of the doped layer is gallium nitride or aluminum gallium nitride that includes the receptor-type doped element, so that the two-dimensional electron gas in the gate region can be better exhausted, and the doped layer is in good contact with the barrier layer, which helps improve device performance.

In an implementation, a dielectric structure is disposed on a periphery of the side wall that is of the gate structure and that is close to the doped layer, so that the side wall that is of the gate structure and that is away from the doped layer, a side wall of the dielectric structure, and at least a part of the side wall of the doped layer are flush.

In embodiments of this application, the side wall that is of the gate structure and that is close to the doped layer forms a sunken structure, and the dielectric structure may be disposed on the periphery of the side wall, so that the side wall that is of the gate structure and that is away from the doped layer, the side wall of the dielectric structure, and at least the part of the side wall of the doped layer are flush. That is, the sunken structure is filled by using the dielectric structure. Therefore, when an overall structure is stable, the dielectric structure can better block the leakage channel between the side wall of the gate structure and the side wall of the doped layer, thereby improving device performance.

In an implementation, a dielectric structure is disposed on a periphery of the side wall that is of the gate structure and that is close to the doped layer, so that the side wall that is of the gate structure and that is away from the doped layer and a side wall of the dielectric structure are flush; and at least a part of the side wall of the doped layer and the side wall of the dielectric structure are not parallel.

In embodiments of this application, the side wall that is of the gate structure and that is close to the doped layer forms a sunken structure, and the dielectric structure may be disposed on the periphery of the side wall, so that the side wall that is of the gate structure and that is away from the doped layer and the side wall of the dielectric structure are flush, and at least the part of the side wall of the doped layer and the side wall of the dielectric structure are not parallel. That is, the sunken structure is filled by using the dielectric structure. Certainly, there may be spacing or no spacing between the dielectric structure and the sunken structure. The sunken structure is filled, so that when an overall structure is stable, the dielectric structure can better block the leakage channel between the side wall of the gate structure and the side wall of the doped layer, thereby improving device performance.

In an implementation, a material of the dielectric structure includes at least one of the following materials: SiO₂, SiON, SiNx, AlOx, AlNx, GaOx, and TiOx.

In embodiments of this application, the material of the dielectric structure may be a material with good insulation, so as to better block the leakage channel between the side wall of the gate structure and the side wall of the doped layer, thereby improving device performance.

In an implementation, in a plane parallel to a surface of the channel layer, the dielectric structure surrounds the gate structure, and widths of a plurality of parts that are of the dielectric structure and that are located on different sides of the gate structure are not completely the same. In embodiments of this application, the dielectric structure may surround the gate structure from all side surfaces, to fill, from all side walls, the sunken structure of the side wall that is of the gate structure and that is close to the doped layer. The widths of the plurality of parts that are of the dielectric structure and that are located on different sides are not completely the same, so that the device can adapt to more application scenarios.

In an implementation, a size of the dielectric structure in a direction perpendicular to the surface of the channel layer is less than 5 microns.

In embodiments of this application, the thickness of the dielectric structure is less than 5 microns, so that the thickness of the dielectric structure is relatively small. In this way, when the dielectric structure is etched, regardless of dry etching or wet etching, a damage caused to the barrier layer is relatively small, thereby improving device performance.

In an implementation, a material of the gate structure includes at least one of the following materials: Ti, TiN, W, Ni, NiV, Ta, TaN, Pd, Pt, WSi₂, and Au.

In embodiments of this application, the material of the gate structure may be a material with relatively good conductivity, to improve device performance.

In an implementation, the semiconductor device further includes:
a source and a drain, where the source and the drain are located on the side that is of the barrier layer and that is away from the channel layer, and the source and the drain are located on two sides of the gate region.

In embodiments of this application, the source and the drain on the two sides of the gate region may be further included, to form a complete device and implement relatively high device performance.

In an implementation, the semiconductor device further includes:
a substrate, where the substrate is located on a side that is of the channel layer and that is away from the barrier layer.

In embodiments of this application, the substrate may be disposed on the side that is of the channel layer and that is away from the barrier layer, to support a film layer disposed on the substrate, thereby improving reliability of the device.

In an implementation, the semiconductor device further includes:
a buffer layer located between the substrate and the channel layer.

In embodiments of this application, the buffer layer may be further disposed between the substrate and the channel layer, so as to improve quality of the channel layer, thereby improving device performance.

According to a second aspect of embodiments of this application, a semiconductor device manufacturing method is provided, and includes:
sequentially forming a barrier layer, a doped material layer, and a dielectric material layer on a channel layer, where the channel layer is made of a group III nitride material, the barrier layer is made of a group III nitride material, the barrier layer has a gate region, and a material of the doped material layer is a group III-V compound including a receptor-type doped element;
etching the dielectric material layer located in the gate region and located on the doped material layer, to form a gate region groove that runs through the dielectric material layer;
depositing a gate material, so that the gate material fills the gate region groove and covers the dielectric material layer; and
etching the gate material, the dielectric material layer, and the doped material layer to form a doped layer located in the gate region and a gate structure that is on the doped layer, where a dielectric structure is disposed on a periphery of a side wall that is of the gate structure and that is close to the doped layer, so that a side wall that is of the gate structure and that is away from the doped layer and a side wall of the dielectric structure are flush.

In an implementation, a material of the channel layer is gallium nitride, a material of the barrier layer is aluminum gallium nitride, and a material of the doped layer is gallium nitride or aluminum gallium nitride that includes the receptor-type doped element.

In an implementation, the side wall of the dielectric structure and at least a part of a side wall of the doped layer are flush: and/or at least a part of the side wall of the doped layer and the side wall of the dielectric structure are not parallel.

In an implementation, before the etching the gate material, the dielectric material layer, and the doped material layer, the method further includes:
forming a hard mask layer on the gate material: and etching the hard mask layer while etching the gate material, the dielectric material layer, and the doped material layer: and
after the etching the gate material, the dielectric material layer, and the doped material layer, the method further includes:
etching the gate structure through wet etching and by using the hard mask layer as a mask, so that at least one side wall of the gate structure is flush.

In an implementation, after the etching the gate structure through wet etching, the method further includes:
removing the hard mask layer, and/or removing the dielectric structure.

In an implementation, a material of the dielectric structure includes at least one of the following materials: SiO₂, SiON, SiNx, AlOx, AlNx, GaOx, and TiOx.

In an implementation, in a plane parallel to a surface of the channel layer, the dielectric structure surrounds the gate structure, and widths of a plurality of parts that are of the dielectric structure and that are located on different sides of the gate structure are not completely the same.

In an implementation, a size of the dielectric structure in a direction perpendicular to the surface of the channel layer is less than 5 μm.

In an implementation, the etching the dielectric material layer located in the gate region and located on the doped material layer is implemented through dry etching or wet etching.

In an implementation, a material of the gate structure includes at least one of the following materials: Ti, TiN, W, Ni, NiV, Ta, TaN, Pd, Pt, WSi₂, and Au.

In an implementation, the method further includes:
forming a source and a drain on the barrier layer, where the source and the drain are located on two sides of the gate region.

In an implementation, a substrate is disposed on a side that is of the channel layer and that is away from the barrier layer.

In an implementation, a buffer layer is disposed between the channel layer and the substrate.

According to a third aspect of embodiments of this application, an electronic device is provided, and includes a circuit board and the semiconductor device that is connected to the circuit board and that is provided in the first aspect of this application.

According to the foregoing technical solutions, it can be learned that embodiments of this application have the following advantages.

Embodiments of this application provide the semiconductor device and the manufacturing method thereof. The semiconductor device may include the channel layer and the barrier layer that are sequentially stacked, the doped layer, and the gate structure. The channel layer and the barrier layer each are made of the group III nitride material. The barrier layer has the gate region. The doped layer is located on the side that is of the barrier layer and that is away from the channel layer. The doped layer is located in the gate region. The material of the doped layer is the group III-V compound including the receptor-type doped element. The gate structure is located on the side that is of the doped layer and that is away from the channel layer. The side wall that is of the gate structure and that is close to the doped layer is retracted relative to the side wall of the doped layer, and the side wall that is of the gate structure and that is close to the doped layer is retracted relative to the side wall that is of the gate structure and that is away from the doped layer, so that the side wall of the gate structure and the side wall of the doped layer are not in the same plane. The retraction structure of the side wall that is of the gate structure and that is close to the doped layer blocks contact between the side wall that is of the gate structure and that is away from the doped layer and the side wall of the doped layer, which is equivalent to blocking the leakage channel between the gate structure and the doped layer, thereby reducing the leakage current of the device and improving the device performance.

### BRIEF DESCRIPTION OF DRAWINGS

To clearly understand implementations of this application, the following briefly describes accompanying drawings used for describing implementations of this application. It is clear that, the accompanying drawings show merely some embodiments of this application.

FIG. 1 is a diagram of a structure of a gallium nitride device:

FIG. 2 to FIG. 9 are diagrams of structures of semiconductor devices according to embodiments of this application:

FIG. 10 is a flowchart of a semiconductor device manufacturing method according to an embodiment of this application: and

FIG. 11 to FIG. 22 are diagrams of structures of devices in a semiconductor device manufacturing process according to embodiments of this application.

### DESCRIPTION OF EMBODIMENTS

Embodiments of this application provide a semiconductor device and a manufacturing method thereof, to improve optical-to-electrical conversion efficiency of the device.

In the specification, claims, and accompanying drawings of this application, the terms “first”, “second”, “third”, “fourth”, and the like (if existent) are intended to distinguish between similar objects but do not necessarily indicate a specific order or sequence. It should be understood that the data termed in such a way is interchangeable in proper circumstances so that embodiments of described herein can be implemented in orders other than the order illustrated or described herein. Moreover, the terms “include”, “contain” and any other variants mean to cover the non-exclusive inclusion, for example, a process, method, system, product, or device that includes a list of steps or units is not necessarily limited to those steps or units, but may include other steps or units not expressly listed or inherent to such a process, method, product, or device.

This application is described in detail with reference to the diagram. For ease of description, when embodiments of this application are described in detail, a sectional view of a device structure is not partially enlarged in a general proportion, and the diagram is merely an example, and should not limit the protection scope of this application. In addition, sizes of the length, width, and depth in a three-dimensional space should be included in actual production.

In a gallium nitride device, a doped layer may be formed on an AlGaN/GaN heterostructure surface of a gate region, a gate structure is formed on the doped layer, and stacked doped layer and gate structure are formed. The doped layer may be a p-type GaN (p-GaN) layer or a p-type AlGaN (p-AlGaN) layer. The doped layer may exhaust a two-dimensional electronic gas channel in the gate region, and a non-gate region outside the gate region does not form the doped layer, so that the gate region has no channel, and the non-gate region has a channel. In this way, a gate is used to control the channel.

However, when the gallium nitride device of this structure works (i.e., operates), a leakage channel is formed between a side wall of the gate and a side wall of the doped layer. Consequently, an electrical parameter such as gate leakage (Igleak) is affected. This is because in an etching process of the gate structure and the doped layer, an etching damage is inevitably formed on the side wall of the gate structure and the side wall of the doped layer, and a leakage current is formed by capturing a charge at a damaged position.

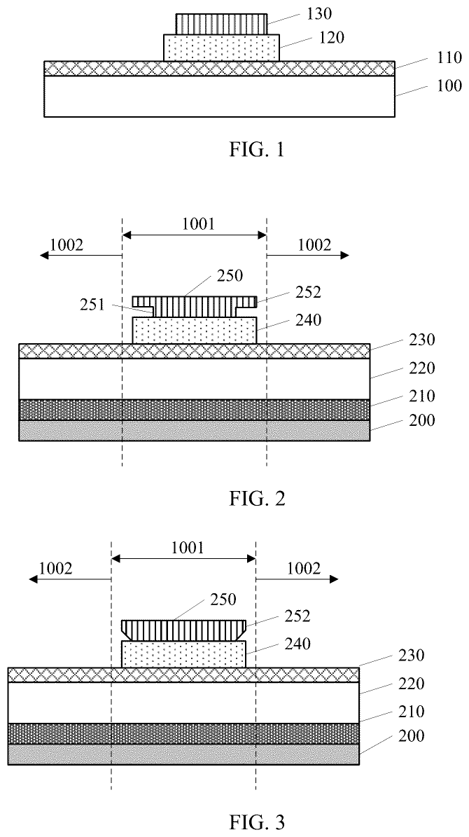

FIG. 1 is a diagram of a structure of a gallium nitride device. The gallium nitride device may include a GaN layer 100 and an AlGaN layer 110 that are disposed in a stacked manner. The AlGaN layer 110 may include a doped layer 120 located in a gate region of an AlGaN/GaN heterostructure surface, and a gate structure 130 located on the doped layer 120, and a transverse size of the gate structure 130 is less than a transverse size of the doped layer 120, so that a stepped structure is formed between the gate structure 130 and the doped layer 120. In this way, a side wall of the gate structure and a side wall of the doped layer are not in a same plane, and the two are discontinuous, thereby preventing the side wall of the gate structure and the side wall of the doped layer from forming a leakage channel, and improving performance of an HEMT device formed based on an AlGaN/GaN heterostructure.

Currently, the gate structure and the doped layer may be obtained through hard mask etching, so that the side wall of the gate structure and the side wall of the doped layer are flush, and then the gate structure is laterally etched by using wet etching, so that the side wall of the gate structure is retracted relative to the side wall of the doped layer, and a connection between the side wall of the gate structure and the side wall of the doped layer is blocked, thereby avoiding the side wall of the gate structure and the side wall of the doped layer from forming the leakage channel. However, when the gate structure is laterally etched by using wet etching to obtain the stepped structure between the gate structure and the doped layer, the side wall of the gate structure is prone to form a thin metamorphic layer during an etching process, which affects etching of the side wall of the gate structure. Consequently, when the stepped structure is formed, the side wall of the gate structure is not flat and is in a sawtooth shape, affecting a subsequent manufacturing process, and the obtained stepped structure is in a poor shape.

Based on the foregoing technical problems, embodiments of this application provide a semiconductor device and a manufacturing method thereof. The semiconductor device may include a channel layer and a barrier layer that are sequentially stacked, a doped layer, and a gate structure. The barrier layer has a gate region. The channel layer and the barrier layer each are made of a group III nitride material. The doped layer is located on a side that is of the barrier layer and that is away from the channel layer. The doped layer is located in the gate region. A material of the doped layer is a group III-V compound including a receptor-type doped element. The gate structure is located on a side that is of the doped layer and that is away from the channel layer. A side wall that is of the gate structure and that is close to the doped layer is retracted relative to a side wall of the doped layer, and the side wall that is of the gate structure and that is close to the doped layer is retracted relative to a side wall that is of the gate structure and that is away from the doped layer, so that the side wall of the gate structure and the side wall of the doped layer are not in a same plane. A retraction structure of the side wall that is of the gate structure and that is close to the doped layer blocks contact between the side wall that is of the gate structure and that is away from the doped layer and the side wall of the doped layer, which is equivalent to blocking a leakage channel between the gate structure and the doped layer, thereby reducing a leakage current of the device and improving device performance.

To make the objectives, features, and advantages of this application clearer and more understandable, the following describes implementations of this application in detail with reference to the accompanying drawings.

FIG. 2 is a diagram of a structure of a semiconductor device according to an embodiment of this application. The semiconductor device may include a channel layer 220, a barrier layer 230, a doped layer 240, and a gate structure 250 that are sequentially disposed in a stacked manner. The channel layer 220 is made of a group III nitride material, and the barrier layer 230 is made of a group III nitride material. For example, a material of the channel layer 220 may be gallium nitride, and a material of the barrier layer 230 may be one of aluminum gallium nitride, aluminum nitride, and the like. In this case, the channel layer 220 and the barrier layer 230 form a heterostructure, for example, an AlGaN/GaN heterostructure. In this way, two-dimensional electron gas is generated, and a semiconductor device formed on this basis may work by using the two-dimensional electron gas generated by the heterostructure. The semiconductor device may be, for example, a high-electron-mobility transistor (HEMT) device based on a heterostructure.

In an implementation, the thickness of the channel layer 220 may be relatively large. In this case, the channel layer 220 may be used as a substrate, and the substrate supports a film layer that is on the substrate. For example, the channel layer 220 whose material is gallium nitride may be used as the substrate, and is also used as a composition component of the AlGaN/GaN heterostructure.

In an implementation, the thickness of the channel layer 220 may be relatively small. In this case, the channel layer 220 may be formed on the substrate 200, the substrate 200 is disposed on a side that is of the channel layer 220 and that is away from the barrier layer 230, the substrate 200 supports a film layer that is on the substrate, the channel layer 220 is used as a composition component of a heterostructure, and a material of the substrate 200 may be a group III-V compound semiconductor material, and may be one or more of aluminum nitride (AlN), silicon (Si), silicon carbide (SiC), or sapphire. Optionally, a buffer layer 210 may be further disposed between the substrate 200 and the channel layer 220. A material of the buffer layer 210 may be aluminum nitride, or may be gallium nitride growing at a low temperature. When the buffer layer 210 is made of gallium nitride growing at a low temperature, the channel layer 220 may be a layer made of gallium nitride growing at a high temperature. In this way, the low-temperature gallium nitride layer is used as the buffer layer 210 between the high-temperature gallium nitride layer and the substrate 200, thereby improving epitaxial quality of the high-temperature gallium nitride layer.

The barrier layer 230 may have a gate region 1001 and a non-gate region 1002 that is on a periphery of the gate region 1001. The gate region 1001 is a region on a surface of the barrier layer 230, and includes space defined by the surface of the barrier layer 230 and countless straight lines perpendicular to the surface of the barrier layer 230. The gate region 1001 is used to form the gate structure 250. A size of the gate region 1001 may be greater than or equal to that of a region in which the gate structure 250) is located. In FIG. 2, a dashed-line box in the middle represents the gate region 1001, and two sides of the gate region 1001 represent the non-gate region 1002. A same representation manner is used in subsequent diagrams of structures. Because FIG. 2 is a sectional view: the non-gate region 1002 may be actually located on the two sides of the gate region 1001, and may form an annular region, such as a ring region or a polygon region, surrounding the gate region 1001.

In this embodiment of this application, the doped layer 240 may be formed on the surface of the barrier layer 230 in the gate region 1001. In other words, the doped layer 240 is disposed on a side that is of the barrier layer 230 and that is away from the channel layer 220, and the doped layer 240 is located in the gate region 1001. A material of the doped layer 240 may be a group III-V compound including a receptor-type doped element. For example, the material of the doped layer 240 may be gallium nitride or aluminum gallium nitride including the receptor-type (P-type) doped element. Correspondingly, the doped layer may be represented as p-type GaN (p-GaN) or p-type AlGaN (p-AlGaN). The doped layer 240 may be configured to exhaust a two-dimensional electronic gas channel of the gate region 1001, and the non-gate region 1002 outside the gate region 1001 does not form the doped layer, so that the gate region 1001 has no channel, and the non-gate region 1002 has a channel. In this way, the gate structure 250 is used to control the channel.

In this embodiment of this application, the gate structure 250 is formed on the doped layer 240, and the gate structure 250 is disposed on a side that is of the doped layer 240 and that is away from the channel layer 220. A material of the gate structure 250 may have good conductivity, and the material of the gate structure 250 may be at least one of Ti, TiN, W, Ni, NiV, Ta, TaN, Pd, Pt, WSi₂, and Au.

In this embodiment of this application, a side wall that is of the gate structure 250) and that is close to the doped layer 240 is retracted relative to a side wall of the doped layer 240, and the side wall that is of the gate structure 250 and that is close to the doped layer 240 is retracted relative to a side wall that is of the gate structure 250 and that is away from the doped layer 240, so that in a direction along the surface of the barrier layer 230, a size of a part that is of the gate structure 250 and that is close to the doped layer 240 is less than a size of a part that is of the gate structure 250) and that is away from the doped layer 240, and less than a size of the doped layer 240. The part that is of the gate structure 250) and that is close to the doped layer 240 forms a sunken structure as a whole, so that the side wall of the gate structure 250 and the side wall of the doped layer 240 are not in a same plane, thereby blocking continuity of the side wall of the gate structure 250 and the side wall of the doped layer 240, and preventing a leakage channel from being formed between the side wall of the gate structure 250) and the side wall of the doped layer 240.

Refer to FIG. 2. The gate structure 250 has a side wall 251 close to the doped layer 240 as one part of side walls of the gate structure 250, and a side wall 252 away from the doped layer 240) as the other part of the side walls of the gate structure 250. The two parts of side walls jointly form the side walls of the gate structure 250. The side wall 251 close to the doped layer 240 not only is retracted relative to the side wall of the doped layer 240, but also is retracted relative to the side wall away from the doped layer 240, to form the retraction structure, so that the side wall of the gate structure 250) and the side wall of the doped layer 250 are not in a same plane. Because the retraction structure of the side wall 251 that is of the gate structure 250 and that is close to the doped layer 240 blocks continuity of the side wall of the gate structure 250 and the side wall of the doped layer 240, which is equivalent to blocking a leakage channel between the gate structure 250 and the doped layer 240, a leakage current of the device is reduced, and device performance is improved.

FIG. 2 is a sectional view: Actually, the gate structure 250 forms a polygonal structure in a plane parallel to the barrier layer 230. In this case, the retraction structure is formed on at least one side wall of the gate structure 250, for example, may be formed on all side walls of the gate structure 250, and the retraction structure forms a closed ring.

In an implementation, the side wall 251 that is of the gate structure 250 and that is close to the doped layer 240 is perpendicular to a surface that is of the doped layer 240 and that faces the gate structure 250. In other words, an included angle between the side wall and a part of a surface that is of the doped layer 240, that faces the gate structure 250, and that is not covered by the gate structure 250 is equal to 90°, as shown in FIG. 2. The side wall 251 that is of the gate structure 250) and that is close to the doped layer 240 and the side wall of the doped layer 240 are discontinuous, and the side wall 251 and the side wall 252 that is of the gate structure 250 and that is away from the doped layer 240) are also discontinuous. Therefore, contact between the side wall 252 that is of the gate structure 250 and that is away from the doped layer 240 and the side wall of the doped layer 240 can be blocked, so that the leakage channel between the gate structure 250 and the doped layer 240 can be blocked. Therefore, the leakage current of the device is reduced, and the device performance is improved.

In an implementation, the side wall 251 that is of the gate structure 250 and that is close to the doped layer 240 may not be perpendicular to a surface that is of the doped layer 240 and that faces the gate structure 250. In other words, an included angle between the side wall and a part of a surface that is of the doped layer 240, that faces the gate structure 250), and that is not covered by the gate structure 250) is not equal to 90°, for example, is less than 90°. FIG. 3 is a diagram of a structure of another semiconductor device according to an embodiment of this application. The side wall 251 that is of the gate structure 250 and that is close to the doped layer 240 and the side wall of the doped layer 240 are discontinuous, the side wall 251 that is of the gate structure 250) and that is close to the doped layer 240 intersects with the part of the surface that is of the doped layer 240, that faces the gate structure 250), and that is not covered by the gate structure 250, and an included angle in intersection is not equal to 90°, for example, is less than 90°. In addition, the side wall 251 that is of the gate structure 250) and that is close to the doped layer 240 intersects with the side wall 252 that is of the gate structure 250) and that is away from the doped layer 240, and an included angle in intersection is not equal to 90°, for example, is greater than 90°. Therefore, when the side wall 251 that is of the gate structure 250 and that is close to the doped layer 240 is not perpendicular to the surface that is of the doped layer 240 and that faces the gate structure 250, contact between the side wall 252 that is of the gate structure 250 and that is away from the doped layer 240 and the side wall of the doped layer 240 can still be blocked, so that the leakage channel between the gate structure 250) and the doped layer 240 can be blocked. Therefore, the leakage current of the device is reduced, and the device performance is improved.

In this embodiment of this application, a dielectric structure 260 may be disposed at a periphery of the side wall 251 that is of the gate structure 250 and that is close to the doped layer 240. FIG. 4 is a diagram of a structure of still another semiconductor device according to an embodiment of this application. There is a dielectric material in the retraction structure of the side wall 251 that is of the gate structure 250) and that is close to the doped layer 240, to form the dielectric structure 260, and the retraction structure is filled with the dielectric material, so that a side wall of the formed dielectric structure 260) and the side wall 252 that is of the gate structure 250) and that is away from the doped layer 240 are flush. In this way, the side wall of the dielectric structure 260 is located between the side wall 252 that is of the gate structure 250 and that is away from the doped layer 240 and the side wall of the doped layer 240, so that the dielectric material is used to block the leakage channel between the gate structure 250 and the doped layer 240. A material of the dielectric structure 260 may be a material with relatively good insulation, and the material of the dielectric structure 260) may be at least one of SiO₂, SiON, SiNx, AlOx, AlNx, GaOx, and TiOx.

In this embodiment of this application, the side wall of the dielectric structure 260 and the side wall 252 that is of the gate structure 250 and that is away from the doped layer 240 are flush. The side wall of the dielectric structure 260 and at least a part of the side wall of the doped layer 240 may be flush. The side wall of the dielectric structure 260 and the entire side wall of the doped layer 240 may be flush, or the side wall of the dielectric structure 260 and a part of the side wall of the doped layer 240 may be flush.

In an implementation, the side wall 252 that is of the gate structure 250) and that is away from the doped layer 240, the side wall of the dielectric structure 260, and the side wall of the doped layer 240 are flush, as shown in FIG. 4. In this case, the side wall 251 that is of the gate structure 250) and that is close to the doped layer 240 and the side wall of the doped layer 240 are not in a same plane, and the side wall of the dielectric structure 260 is located between the side wall 252 that is of the gate structure 250) and that is away from the doped layer 240 and the side wall of the doped layer 240, so that the leakage channel between the gate structure 250 and the doped layer 240 is blocked by using the dielectric material.

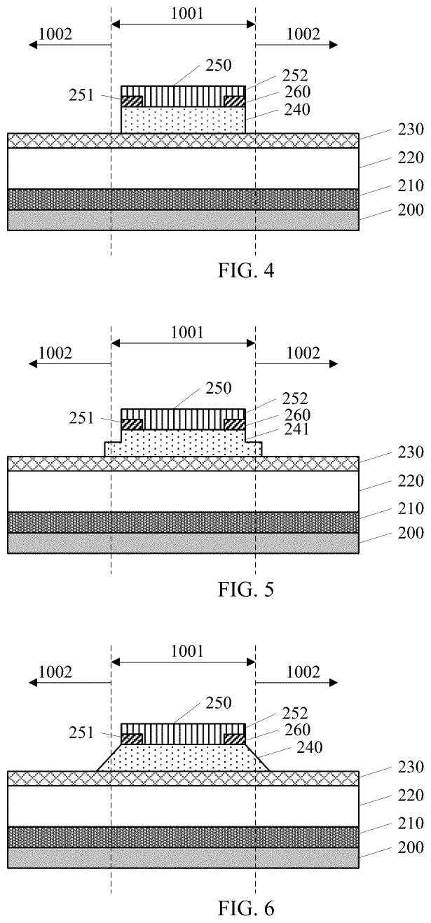

In an implementation, the side wall 252 that is of the gate structure 250 and that is away from the doped layer 240, the side wall of the dielectric structure 260, and a part of the side wall of the doped layer 240 are flush. FIG. 5 is a diagram of a structure of yet another semiconductor device according to an embodiment of this application. The side wall of the doped layer 240 includes a side wall 241 close to the gate structure 250) and a side wall 242 away from the gate structure 250. The side wall 241 that is of the doped layer 240 and that is close to the gate structure 250, the side wall 252 that is of the gate structure 250 and that is away from the doped layer 240, and the side wall of the dielectric structure 260) are flush, and the side wall 242 that is of the doped layer 240 and that is away from the gate structure 250 and the side wall of the dielectric structure 260 are not flush. The side wall 242 that is of the doped layer 240 and that is away from the gate structure 250 may be parallel to the side wall of the dielectric structure 260, or may be not parallel to the side wall of the dielectric structure 260).

In this embodiment of this application, the side wall of the dielectric structure 260 and the side wall 252 that is of the gate structure 250 and that is away from the doped layer 240 are flush. The side wall of the dielectric structure 260 and at least a part of the side wall of the doped layer 240 may not be parallel. The side wall of the dielectric structure 260 may not be parallel to the entire side wall of the doped layer 240, or may not be parallel to a part of the side wall of the doped layer 240.

In an implementation, the side wall 252 that is of the gate structure 250 and that is away from the doped layer 240 and the side wall of the dielectric structure 260 are flush, and the side wall of the doped layer 240 is not parallel to the side wall of the dielectric structure 260. FIG. 6 is a diagram of a structure of still yet another semiconductor device according to an embodiment of this application. An included angle between the side wall of the doped layer 240 and the side wall of the dielectric structure 260 is not equal to 90°, for example, is greater than 90°. Finally, a structure in which the side wall of the gate structure 250 and the side wall of the doped layer 250 are not in a same plane is formed.

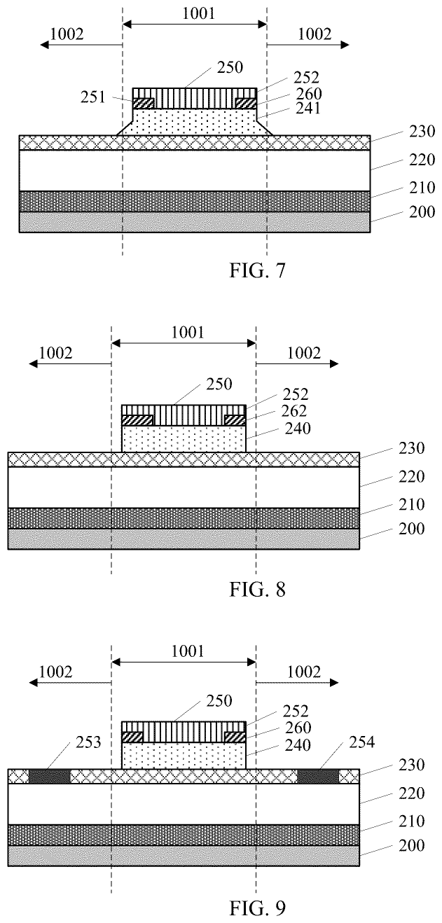

In an implementation, the side wall 252 that is of the gate structure 250 and that is away from the doped layer 240 and the side wall of the dielectric structure 260 are flush, a part of the side wall of the doped layer 240 is not parallel to the side wall of the dielectric structure 260, and the other part of the side wall of the doped layer 240 and the side wall of the dielectric structure 260 may be flush or not flush. FIG. 7 is a diagram of a structure of a further semiconductor device according to an embodiment of this application. The side wall of the doped layer 240 includes a side wall 241 close to the gate structure 250) and a side wall 242 away from the gate structure 250. The side wall 241 that is of the doped layer 240 and that is close to the gate structure 250, the side wall 252 that is of the gate structure 250) and that is away from the doped layer 240, and the side wall of the dielectric structure 260 are flush. The side wall 242 that is of the doped layer 240 and that is away from the gate structure 250 is not parallel to the side wall of the dielectric structure 260, and an included angle between the side wall 242 and the side wall of the dielectric structure 260 is not equal to 90°, for example, is greater than 90°.

It can be learned that, for a requirement that the side wall of the gate structure 250 and the side wall of the doped layer 240 not be in a same plane, embodiments of this application provide a plurality of designs of the side wall of the gate structure 250 and the side wall of the doped layer 240, to meet a plurality of requirements in actual application, and there is a relatively large application prospect.

In embodiments of this application. FIG. 4 to FIG. 7 are sectional views. Therefore, in a plane parallel to a surface of the channel layer 220, the retraction structure may be located on side walls of the gate structure 250), and the dielectric structure 260) may surround the gate structure 250.

In actual application, when the dielectric structure 260 surrounds the gate structure 250, in the plane parallel to the surface of the channel layer 220, widths of a plurality of parts that are of the dielectric structure 260) and that are located on different sides of the gate structure 250) are not completely the same. The width herein refers to a distance between the side wall of the dielectric structure 260) and the side wall 251 that is of the gate structure 250 and that is close to the doped layer 240. FIG. 8 is a diagram of a structure of a still further semiconductor device according to an embodiment of this application. The width of a first part 261, of the dielectric structure 260, located on a left side of the gate structure 250 is greater than the width of a second part 262, of the dielectric structure 260, located on a right side of the gate structure 250. In this way, a design of the gate structure 250) of an asymmetric structure can meet personalized design requirements of some devices, and has a relatively large application prospect.

In embodiments of this application, a size of the dielectric structure in a direction perpendicular to the surface of the channel layer 220 is less than 5 microns (μm), for example, less than 500 nm. That is, a film layer formed by the dielectric material is relatively thin. When the dielectric structure 260 is obtained through etching, damage to a surface of the doped layer 240 is reduced, a leakage current caused by the etching damage is avoided, and device performance is improved.

In this embodiment of this application. FIG. 9 is a diagram of a structure of a yet further semiconductor device according to an embodiment of this application. The semiconductor device may further include a source 253 and a drain 254. The source 253 and the drain 254 are in the non-gate region 1002 and located on a side that is of the barrier layer 230 and that is away from the channel layer 220, and the source 253 and the drain 254 are located on the two sides of the gate region 1001. Both the source 253 and the drain 254 are made of materials with relatively good conductivity, and the materials of the source 253 and the drain 254 are at least one of Ti, TiN, W, Ni, NiV, Ta, TaN, Pd, Pt, WSi₂, and Au.

Embodiments of this application provide the semiconductor device. The semiconductor device may include the channel layer and the barrier layer that are sequentially stacked, the doped layer, and the gate structure. The channel layer and the barrier layer each are made of the group III nitride material. The barrier layer has the gate region. The doped layer is located on the side that is of the barrier layer and that is away from the channel layer. The doped layer is located in the gate region. The material of the doped layer is the group III-V compound including the receptor-type doped element. The gate structure is located on the side that is of the doped layer and that is away from the channel layer. The side wall that is of the gate structure and that is close to the doped layer is retracted relative to the side wall of the doped layer, and the side wall that is of the gate structure and that is close to the doped layer is retracted relative to the side wall that is of the gate structure and that is away from the doped layer, so that the side wall of the gate structure and the side wall of the doped layer are not in the same plane. The retraction structure of the side wall that is of the gate structure and that is close to the doped layer blocks contact between the side wall that is of the gate structure and that is away from the doped layer and the side wall of the doped layer, which is equivalent to blocking the leakage channel between the gate structure and the doped layer, thereby reducing the leakage current of the device and improving the device performance.

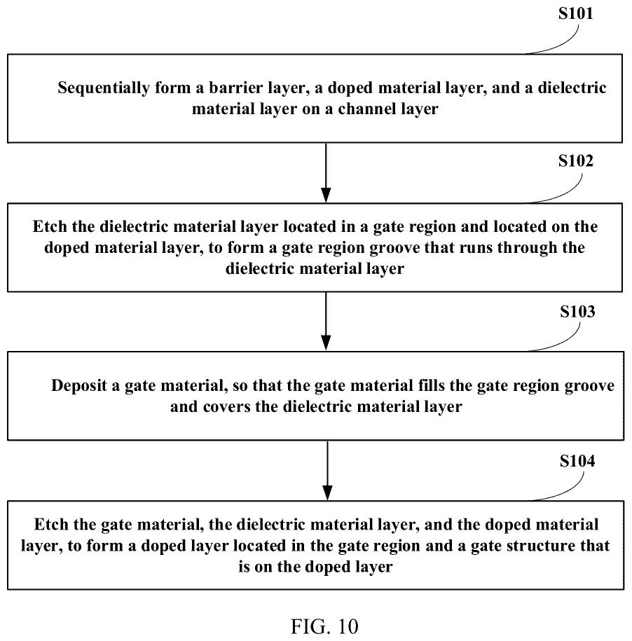

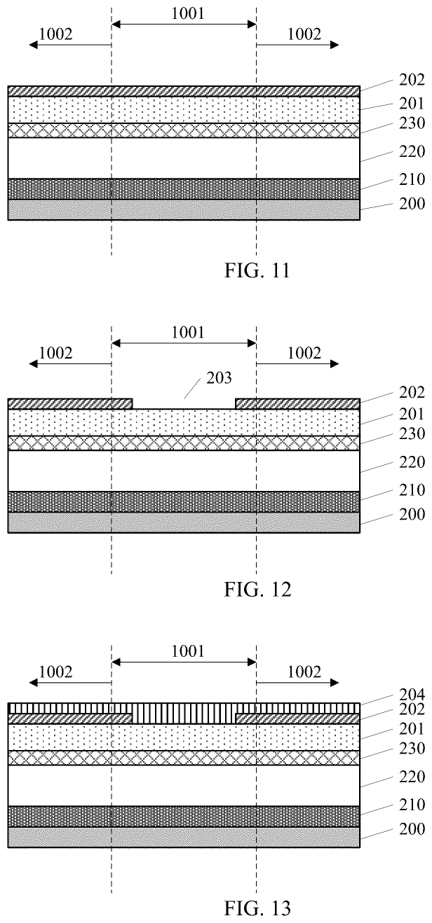

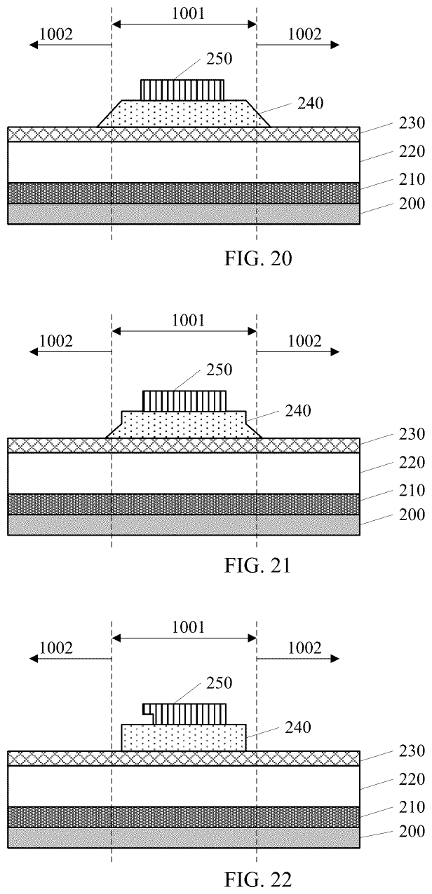

Based on the semiconductor device provided in embodiments of this application, an embodiment of this application further provides a semiconductor device manufacturing method. FIG. 10 is a flowchart of a semiconductor device manufacturing method according to an embodiment of this application. FIG. 11 to FIG. 22 are diagrams of structures of semiconductor devices in a manufacturing process. The method may include the following steps.

S101: Sequentially form a barrier layer 230, a doped material layer 201, and a dielectric material layer 202 on a channel layer 220, as shown in FIG. 11.

In this embodiment of this application, the channel layer 220 is made of a group III nitride material, and the barrier layer 230 is made of a group III nitride material. For example, a material of the channel layer 220 may be gallium nitride, and a material of the barrier layer 230 may be aluminum gallium nitride. In this case, the channel layer 220 and the barrier layer 230 that are disposed in a stacked manner form an AlGaN/GaN heterostructure. In this way, two-dimensional electron gas is generated, and a semiconductor device formed on this basis may work by using the two-dimensional electron gas generated by the heterostructure. The semiconductor device may be, for example, a high-electron-mobility transistor (HEMT) device based on a heterostructure.

In an implementation, the thickness of the channel layer 220 may be relatively large. In this case, the channel layer 220 may be used as a substrate, and the substrate supports a film layer that is on the substrate. For example, the channel layer 220 whose material is gallium nitride may be used as the substrate, and is also used as a composition component of the AlGaN/GaN heterostructure.

In an implementation, the thickness of the channel layer 220 may be relatively small. Refer to FIG. 11. The channel layer 220 may be formed on the substrate 200, the substrate 200 supports a film layer that is on the substrate, the channel layer 220 is used as a composition component of a heterostructure, and a material of the substrate 200 may be a group III-V compound semiconductor material, and may be one or more of aluminum nitride (AlN), silicon (Si), silicon carbide (SiC), or sapphire. Optionally, a buffer layer 210 may be further disposed between the substrate 200 and the channel layer 220. A material of the buffer layer 210 may be aluminum nitride, or may be gallium nitride growing at a low temperature.

During implementation, the buffer layer 210 may be first formed on a surface of the substrate 200, then the channel layer 220 is formed on the buffer layer 210, and then the barrier layer 230, the doped material layer 201, and the dielectric material layer 202 are sequentially formed on the channel layer 220. The channel layer 220, the barrier layer 230, the doped material layer 201, and the dielectric material layer 202 may be formed in a metal organic chemical vapor deposition (MOCVD) manner.

In this embodiment of this application, the barrier layer 230 may have a gate region 1001 and a non-gate region 1002 that is on a periphery of the gate region 1001. The gate region 1001 is a region on a surface of the barrier layer 230, and includes space defined by the surface of the barrier layer 230 and countless straight lines perpendicular to the surface of the barrier layer 230. The gate region 1001 is used to form a gate structure 250. A size of the gate region 1001 may be greater than or equal to that of a region in which the gate structure 250 is located. In FIG. 11, a dashed-line box in the middle represents the gate region 1001, and two sides of the gate region 1001 represent the non-gate region 1002. A same representation manner is used in subsequent diagrams of structures. Because FIG. 11 is a sectional view; the non-gate region 1002 may be actually located on the two sides of the gate region 1001, and may form an annular region, such as a ring region or a polygon region, surrounding the gate region 1001.

In this embodiment of this application, a material of the doped material layer 201 may be a group III-V compound including a receptor-type doped element. For example, the material of the doped material layer 201 may be gallium nitride or aluminum gallium nitride including the receptor-type doped element. In other words, the doped layer may be p-type GaN (p-GaN) or p-type AlGaN (p-AlGaN). A material of the dielectric material layer 202 may be an insulation material, and the material of the dielectric material layer 202 may be at least one of SiO₂, SiON, SiNx, AlOx, AlNx, GaOx, and TiOx.

S102: Etch the dielectric material layer 202 located in the gate region 1001 and located on the doped material layer 201, to form a gate region groove 203 that runs through the dielectric material layer 202, as shown in FIG. 12.

In this embodiment of this application, after the dielectric material layer 202 is formed, the dielectric material layer 202 in the gate region 1001 may be etched, to form the gate region groove 203 that runs through the dielectric material layer 202 and that reaches the doped material layer 201. The gate region groove 203 is located in the gate region 1001, and is configured to form the gate structure 250).

During implementation, spin coating of a photoresist may be performed on the dielectric material layer 202, and then processing such as exposure and development is performed on the photoresist to expose the dielectric material layer 202 located in the gate region 1001. Then, the exposed dielectric material layer 202 located in the gate region 1001 is etched to obtain the gate region groove 203 that runs through the dielectric material layer 202. Finally, the photoresist is removed, and the photoresist may be removed through dry etching and wet etching, or may be removed in another manner.

In an actual application, in a direction perpendicular to a surface of the channel layer 220, a size of the dielectric material layer 202 is less than 5 microns (μm), for example, less than 500 nm. That is, a film layer formed by a dielectric material is relatively thin, and it is easy to control etching of the dielectric material layer 202. When the dielectric material layer 202 is etched, damage to a surface of the doped material layer 201 is reduced, a leakage current caused by etching damage is avoided, and device performance is improved. Because the dielectric material layer 202 is relatively thin, the gate region groove 203 may be obtained through dry etching, or the gate region groove 203 may be obtained through wet etching. When the dielectric material layer 202 is etched through wet etching, the dielectric material layer 202 and the doped material layer 201 below the dielectric material layer 202 may each have a relatively high selection ratio, thereby further reducing etching damage to the doped material layer 201.

S103: Deposit a gate material 204, so that the gate material 204 fills the gate region groove 203 and covers the dielectric material layer 202, as shown in FIG. 13.

In this embodiment of this application, after the photoresist is removed, the gate material 204 may continue to be deposited, so that the gate material fills the gate region groove 203 and covers the dielectric material layer 202. The gate material may have good conductivity, and a material of the gate material may be at least one of Ti, TiN, W, Ni, NiV, Ta, TaN, Pd, Pt, WSi₂, and Au. A deposition manner of the gate material 204 may be physical vapor deposition (PVD).

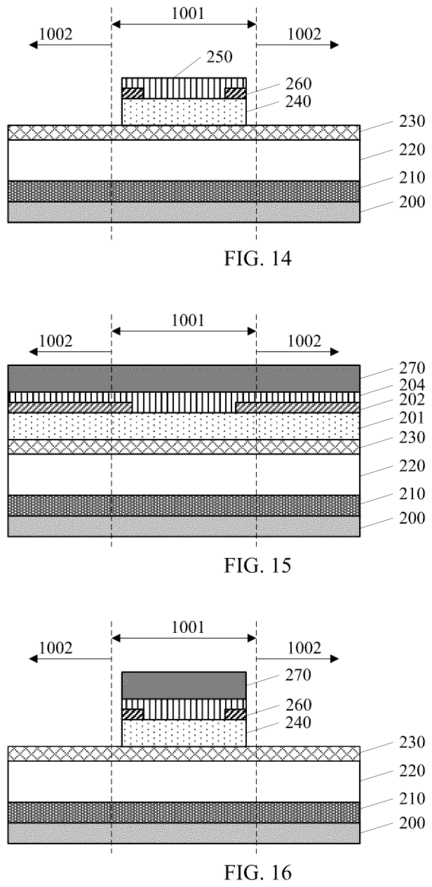

S104: Etch the gate material 204, the dielectric material layer 202, and the doped material layer 201, to form a doped layer 240 located in the gate region 1001 and the gate structure 250 that is on the doped layer 240, as shown in FIG. 14 to FIG. 22.

In this embodiment of this application, after the gate material 204 is deposited, a gate material 204, a dielectric material layer 202, and a doped material layer 201 that are located outside the gate region 1001 are etched, to finally form the doped layer 240 located in the gate region 1001 and the gate structure 250 on the doped layer 240.

In a plane parallel to the surface of the channel layer 220, the width of the doped layer 240 is greater than the width of the gate region groove 203. A dielectric structure 260 is disposed on a periphery of a side wall 251 that is of the finally formed gate structure 250 and that is close to the doped layer 240, so that a side wall 252 that is of the gate structure 250 and that is away from the doped layer 240 and a side wall of the dielectric structure 260 are flush.

During implementation, spin coating of a photoresist may be performed on the gate material 204. In the plane parallel to the surface of the channel layer 220, the width of the photoresist is greater than the width of the gate region groove 203, and then processing such as exposure and development is performed on the photoresist, to expose the gate material 204, the dielectric material layer 202, and the doped material layer 201 that are located outside the gate region 1001. Then, dry etching is sequentially performed on the exposed gate material 204, dielectric material layer 202, and doped material layer 201 that are located outside the gate region 1001, and a gate material 204, a dielectric material layer 202, and a doped material layer 201 that are located in the gate region 1001 are reserved. Finally, the photoresist is removed, and the photoresist may be removed through dry etching and wet etching, or may be removed in another manner.

In this embodiment of this application, when the dielectric material layer 202 is etched, an included angle between a side wall of the gate region groove 203 and a bottom surface of the gate region groove 203 is controlled to be equal to 90°, so that the structure shown in FIG. 2 in which an included angle between the side wall 251 that is of the gate structure 250 and that is close to the doped layer 240 and a part of a surface 241 that is of the doped layer 240, that faces the gate structure 250, and that is not covered by the gate structure 250 is equal to 90° may be formed. When the dielectric material layer 202 is etched, an included angle between a side wall of the gate region groove 203 and a bottom surface of the gate region groove 203 is controlled to be not equal to 90°, for example, to be greater than 90°, so that the structure shown in FIG. 3 in which an included angle between the side wall 251 that is of the gate structure 250 and that is close to the doped layer 240 and a part of a surface 241 that is of the doped layer 240, that faces the gate structure 250, and that is not covered by the gate structure 250 is not equal to 90° may be formed, for example, a structure with the included angle less than 90°.

In embodiments of this application, a manufacturing parameter for etching the gate material 204, the dielectric material layer 202, and the doped material layer 201 may be controlled, to obtain a plurality of stacked structures shown in FIG. 4 to FIG. 7 in which the side wall of the gate structure 250) and the side wall of the doped layer 250 are not in a same plane, to finally form a structure in which the side wall of the dielectric structure 260 and at least a part of the side wall of the doped layer 240 are flush, and/or a structure in which at least a part of the side wall of the doped layer 240 is not parallel to the side wall of the dielectric structure 260.

During implementation, after dry etching is sequentially performed, by using the photoresist, on the exposed gate material 204, dielectric material layer 202, and doped material layer 201 that are located outside the gate region 1001, the photoresist may be trimmed, and then dry etching is sequentially performed, by using a trimmed photoresist, on the exposed gate material 204, dielectric material layer 202, and partially doped material layer 201 that are located outside the gate region 1001, to finally obtain the structure shown in FIG. 5 or FIG. 7 in which at least the part of the side wall of the doped layer 240 is parallel to the side wall of the dielectric structure 260.

In an actual application, when the gate material 204, the dielectric material layer 202, and the doped material layer 201 are etched by using the photoresist, the width of the dielectric material layer 202 that is covered by the photoresist and that is located on the left side of the gate region groove 203 may be set to be greater than the width of the dielectric material layer 202 that is covered by the photoresist and that is located on the right side of the gate region groove 203, to obtain the dielectric structure shown in FIG. 8 in which the width of the first part 261 that is of the dielectric structure 260) and that is located on the left side of the gate structure 250 is greater than the width of the second part 262 that is of the dielectric structure 260 and that is located on the right side of the gate structure 250.

In actual application, after the retraction structure on the side wall 251 that is of the gate structure 250) and that is close to the doped layer 240 is formed, the side wall 251 that is of the gate structure 250) and that is close to the doped layer 240 may be further laterally etched, so that the side walls of the gate structure 250 are flush. The side wall 251 that is of the gate structure 250 and that is close to the doped layer 240 and the side wall 252 that is of the gate structure 250 and that is away from the doped layer 240 are flush. In this case, a stepped structure is formed between the gate structure 250) and the doped layer 240.

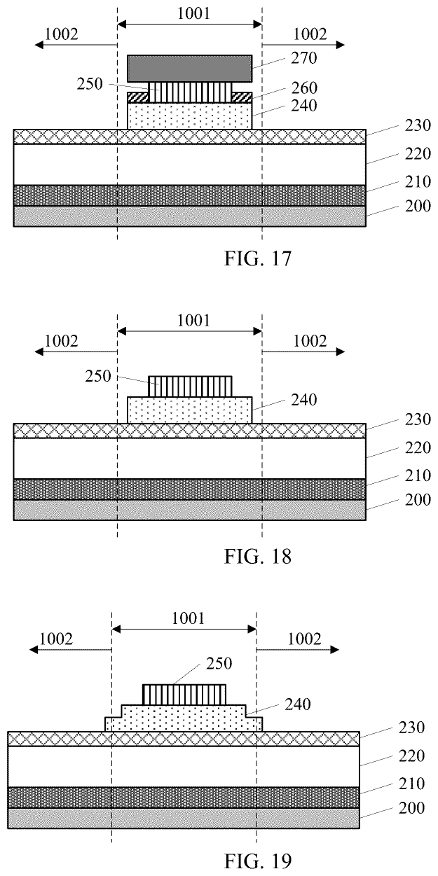

During implementation, after the gate material 204 is deposited and before the gate material 204, the dielectric material layer 202, and the doped material layer 201 are etched, a hard mask layer 270 may be formed on the gate material 204. A forming manner of the hard mask layer 270 may be physical vapor deposition (PVD), as shown in FIG. 15. Then, when the gate material 204, the dielectric material layer 202, and the doped material layer 201 are etched, the hard mask layer 270) is also etched, as shown in FIG. 16. After the retraction structure on the side wall 251 that is of the gate structure 250) and that is close to the doped layer 240 is obtained through etching, the gate structure 250 may be laterally etched by using the hard mask layer 270 as a mask and through wet etching, so that at least one side wall of the gate structure 250 is flush, as shown in FIG. 17. When the gate structure 250 is laterally etched through wet etching, there is the dielectric structure 260) around the side wall 251 that is of the gate structure 250) and that is close to the doped layer 240. Therefore, a distance of wet etching can be better controlled, and the wet etching is only for a part that is of the side wall and that is not covered by the dielectric structure 260. Compared with a case in which the entire side wall of the gate structure is laterally etched through wet etching, this manner can improve stability of a manufacturing process and a shape of the side wall of the gate structure 250.

In this embodiment of this application, after the lateral etching of the gate structure 250 is completed, the hard mask layer 270 is removed. Certainly, the hard mask 270 may alternatively not be removed and used as a protective layer of the gate structure 250. The dielectric structure 260) may or may not be removed. The dielectric structure 260 may be removed when the hard mask layer 270 is removed through wet etching, or the hard mask layer 270 and the dielectric structure 260 may be separately removed through two-step manufacturing. A manufacturing sequence of removing the hard mask layer 270 and the dielectric structure 260 is not limited in this application, provided that the stepped structure between the gate structure 250 and the doped layer 240 is finally formed, as shown in FIG. 18.

In this embodiment of this application, the step of performing lateral etching on the gate structure 250 may be performed on the stacked structures formed by the gate structure 250 and the doped layer 240 shown in FIG. 4 to FIG. 8, to obtain the stepped structure between the gate structure 250 and the doped layer 240, as shown in FIG. 19 to FIG. 22.

During implementation, when the gate structure 250 is laterally etched through wet etching, removed thicknesses of side walls of the gate structure 250 in different directions are the same. For the gate structure 250) of the asymmetric structure shown in FIG. 8, after the lateral etching is completed, at least one side wall of the gate structure 250 may not be flush, as shown in FIG. 22.

It can be learned that the stepped structure that is between the gate structure 250 and the doped layer 240 that is obtained through the foregoing manufacturing post-preparing has a relatively good shape, and the side wall of the gate structure 250 and the surface that is of the doped layer 240 and that is not covered by the gate structure 250 have relatively few etching damages, thereby reducing a leakage current of the device and improving device performance.

In this embodiment of this application, refer to FIG. 9. A source 253 and a drain 254 may further be formed in the non-gate region 1002 that is on the barrier layer 230, and the source 253 and the drain 254 are located on the two sides of the gate region 1001. Both the source 253 and the drain 254 are made of materials with relatively good conductivity, and the materials of the source 253 and the drain 254 are at least one of Ti, TiN, W, Ni, NiV, Ta, TaN, Pd, Pt, WSi₂, and Au.

Embodiments of this application provide the semiconductor device manufacturing method. The barrier layer, the doped material layer, and the dielectric material layer are sequentially formed on the channel layer. The channel layer and the barrier layer each are made of the group III nitride material. The barrier layer has the gate region. The material of the doped material layer is the group III-V compound including the receptor-type doped element. The dielectric material layer located in the gate region and located on the doped material layer is etched, to form the gate region groove that runs through the dielectric material layer. The gate material is deposited, so that the gate material fills the gate region groove and covers the dielectric material layer. The gate material, the dielectric material layer, and the doped material layer are etched, to form the doped layer located in the gate region and the gate structure that is on the doped layer. The dielectric structure is disposed on the periphery of the side wall that is of the gate structure and that is close to the doped layer, so that the side wall that is of the gate structure and that is away from the doped layer and the side wall of the dielectric structure are flush, and the side wall of the gate structure and the side wall of the doped layer are not on a same plane. The dielectric structure of the side wall that is of the gate structure and that is close to the doped layer blocks contact between the side wall that is of the gate structure and that is away from the doped layer and the side wall of the doped layer, which is equivalent to blocking a leakage channel between the gate structure and the doped layer, thereby reducing a leakage current of a device and improving device performance.

Embodiments in this specification are all described in a progressive manner. For same or similar parts in embodiments, refer to each other. Each embodiment focuses on a difference from other embodiments.

The foregoing provides implementations of this application. It should be understood that the foregoing embodiments are merely intended for describing the technical solutions of this application, but not for limiting this application. Although this application is described in detail with reference to the foregoing embodiments, persons of ordinary skill in the art should understand that they may still make modifications to the technical solutions described in the foregoing embodiments or make equivalent replacements to some technical features thereof, without departing from the scope of the technical solutions of embodiments of this application.

What is claimed is:

1. A semiconductor device, comprising:
a channel layer and a barrier layer that are sequentially stacked, the channel layer being made of a group III nitride material, the barrier layer being made of a group III nitride material, and the barrier layer includes a gate region;
a doped layer located on a side of the barrier layer that is away from the channel layer, the doped layer being located in the gate region, and a doped layer material of the doped layer comprises a group III-V compound comprising a receptor-type doped element; and
a gate structure located on a side of the doped layer that is away from the channel layer, a side wall of the gate structure that is close to the doped layer is retracted relative to a side wall of the doped layer, and the side wall of the gate structure that is close to the doped layer is retracted relative to the side wall of the gate structure that is away from the doped layer, so that the side wall of the gate structure and the side wall of the doped layer are not in a same plane.

2. The device according to claim 1, wherein a channel layer material of the channel layer is gallium nitride, a barrier layer material of the barrier layer is aluminum gallium nitride, and a doped layer material of the doped layer is gallium nitride or aluminum gallium nitride.

3. The device according to claim 1, wherein a dielectric structure is disposed on a periphery of the side wall of the gate structure that is close to the doped layer, so that the side wall of the gate structure that is away from the doped layer, a side wall of the dielectric structure, and at least a part of the side wall of the doped layer are flush.

4. The device according to claim 1, wherein a dielectric structure is disposed on a periphery of the side wall of the gate structure that is close to the doped layer, so that the side wall of the gate structure that is away from the doped layer and a side wall of the dielectric structure are flush, and at least a part of the side wall of the doped layer and the side wall of the dielectric structure are not parallel.

5. The device according to claim 3, wherein a dielectric structure material of the dielectric structure comprises at least one of the following materials: SiO₂, SiON, SiNx, AlOx, AlNx, GaOx, or TiOx.

6. The device according to claim 3, wherein in a plane parallel to a surface of the channel layer, the dielectric structure surrounds the gate structure, and widths of a plurality of parts that are of the dielectric structure and that are located on different sides of the gate structure are not completely the same.

7. The device according to claim 3, wherein a size of the dielectric structure in a direction perpendicular to the surface of the channel layer is less than 5 microns.

8. The device according to claim 1, wherein a gate structure material of the gate structure comprises at least one of the following materials: Ti, TiN, W, Ni, NiV, Ta, TaN, Pd, Pt, WSi₂, or Au.

9. The device according to claim 1, further comprising:
a source and a drain, wherein the source and the drain are located on the side of the barrier layer that is away from the channel layer, and the source and the drain are located on two sides of the gate region.

10. The device according to claim 1, further comprising:
a substrate, wherein the substrate is located on a side of the channel layer that is away from the barrier layer.

11. The device according to claim 10, further comprising:
a buffer layer located between the substrate and the channel layer.

12. An electronic device, comprising:
a circuit board; and
a semiconductor device connected to the circuit board, the semiconductor device comprising:
a channel layer and a barrier layer that are sequentially stacked, the channel layer being made of a group III nitride material, the barrier layer being made of a group III nitride material, and the barrier layer includes a gate region;
a doped layer located on a side of the barrier layer that is away from the channel layer, the doped layer being located in the gate region, and a doped layer material of the doped layer comprises a group III-V compound comprising a receptor-type doped element; and
a gate structure located on a side of the doped layer that is away from the channel layer, a side wall of the gate structure that is close to the doped layer is retracted relative to a side wall of the doped layer, and the side wall of the gate structure that is close to the doped layer is retracted relative to the side wall of the gate structure that is away from the doped layer, so that the side wall of the gate structure and the side wall of the doped layer are not in a same plane.

13. The device according to claim 12, wherein a channel layer material of the channel layer is gallium nitride, a barrier layer material of the barrier layer is aluminum gallium nitride, and a doped layer material of the doped layer is gallium nitride or aluminum gallium nitride.

14. The device according to claim 12, wherein a dielectric structure is disposed on a periphery of the side wall of the gate structure that is close to the doped layer, so that the side wall of the gate structure that is away from the doped layer, a side wall of the dielectric structure, and at least a part of the side wall of the doped layer are flush.

15. The device according to claim 12, wherein a dielectric structure is disposed on a periphery of the side wall of the gate structure that is close to the doped layer, so that the side wall of the gate structure that is away from the doped layer and a side wall of the dielectric structure are flush, and at least a part of the side wall of the doped layer and the side wall of the dielectric structure are not parallel.

16. The device according to claim 14, wherein a dielectric structure material of the dielectric structure comprises at least one of the following materials: SiO₂, SiON, SiNx, AlOx, AlNx, GaOx, or TiOx.

17. The device according to claim 14, wherein in a plane parallel to a surface of the channel layer, the dielectric structure surrounds the gate structure, and widths of a plurality of parts that are of the dielectric structure and that are located on different sides of the gate structure are not completely the same.

18. The device according to claim 14, wherein a size of the dielectric structure in a direction perpendicular to the surface of the channel layer is less than 5 microns.

19. The device according to claim 12, further comprising:
a substrate, wherein the substrate is located on a side of the channel layer that is away from the barrier layer.

20. The device according to claim 19, further comprising:
a buffer layer located between the substrate and the channel layer.
